(19) United States
(12) Patent Application Publication
(10) Pub. No.: US 2020/0203209 A1
(43) Pub. Date: Jun. 25, 2020

(54) APPARATUS AND SYSTEM FOR WAFER SPIN PROCESS

(71) Applicant: XIA TAI XIN SEMICONDUCTOR (QING DAO) LTD., Qingdao (CN)

(72) Inventors: Gil-Sung SHIN, Singapore (SG); Chang-Hyeon Nam, Singapore (SG); Injoon Yeo, Singapore (SG)

(21) Appl. No.: 16/661,962

(22) Filed: Oct. 23, 2019

Related U.S. Application Data
(60) Provisional application No. 62/783,220, filed on Dec. 21, 2018.

(51) Int. Cl. H01L 21/687; H01L 21/67

(52) U.S. Cl. CPC H01L 21/68785; H01L 21/6838; H01L 21/67017

(57) ABSTRACT

An apparatus for performing a wafer spin process is provided. The apparatus includes a base member, a rotatable member, and a wafer guide. The base member includes a plurality of first magnetic components. The rotatable member is disposed over the base member and includes a plurality of second magnetic components. The wafer guide is disposed over the rotatable member for holding a wafer.

### CROSS REFERENCE TO RELATED APPLICATION(S)

The present application claims the benefit of U.S. Provisional Application No. 62/783,220, filed on Dec. 21, 2018, the contents of which are incorporated herein by reference.

### FIELD

The present disclosure relates to semiconductor fabrication and, more particularly, to a single semiconductor wafer spin processor.

### BACKGROUND

In semiconductor manufacturing, a spin processor, for example, is used to spray etchants onto the wafer in a chamber. Typically, the spin processor has a motor component installed beneath the wafer. When the temperature of the chamber increases due to prolonged operation of the spin processor, byproducts of the etchants are generated and cause damage to the motor component.

### SUMMARY

The following presents a summary of examples of the present disclosure in order to provide a basic understanding of at least some of its examples. This summary is not an extensive overview of the present disclosure. It is not intended to identify key or critical elements of the present disclosure or to delineate the scope of the present disclosure. The following summary merely presents some concepts of the present disclosure in a general form as a prelude to the more detailed description provided below.

In one example, an apparatus for performing a wafer spin process is provided. The apparatus includes a base member, a rotatable member, and a wafer guide. The base member includes a plurality of first magnetic components. The rotatable member is disposed over the base member and includes a plurality of second magnetic components. The wafer guide is disposed over the rotatable member for holding a wafer.

In another example, a system for performing a wafer spin process is provided. The system includes a chamber and an apparatus disposed in the chamber. The apparatus includes a base member, a rotatable member, and a wafer guide. The base member includes a plurality of first magnetic components. The rotatable member is disposed over the base member and includes a plurality of second magnetic components. The wafer guide is disposed over the rotatable member for holding a wafer.

The details of one or more examples are set forth in the accompanying drawings and description below.

### BRIEF DESCRIPTION OF THE DRAWINGS

The accompanying drawings illustrate one or more implementations of the present disclosure and, together with the written description, explain the principles of the present disclosure. Wherever possible, the same reference numbers are used throughout the drawings referring to the same or like elements of an implementation.

FIG. 1A is a side cross-sectional view of a wafer spin-processing apparatus in accordance with an implementation of the present disclosure.

FIG. 1B is a top cross-sectional view of the rotatable member of the wafer spin-processing apparatus of FIG. 1A.

FIG. 1C is a side view of the wafer spin-processing apparatus of FIG. 1A having capabilities of magnetic levitation and magnetic rotation.

FIG. 1D is a side cross-sectional view of the wafer spin-processing apparatus of FIG. 1A having capabilities of magnetic levitation and magnetic rotation.

FIG. 2 is a side cross-sectional view of a wafer spin-processing system having the wafer spin-processing apparatus of FIG. 1A in accordance with an implementation of the present disclosure.

### DETAILED DESCRIPTION

To facilitate an understanding of the principles and features of the various implementations of the present disclosure, various illustrative implementations are explained below. Although exemplary implementations of the present disclosure are explained in detail, it is to be understood that other implementations are contemplated. Accordingly, it is not intended that the present disclosure is limited in its scope to the details of construction and arrangement of components set forth in the following description or illustrated in the drawings. The present disclosure is capable of other implementations and of being practiced or carried out in various ways.

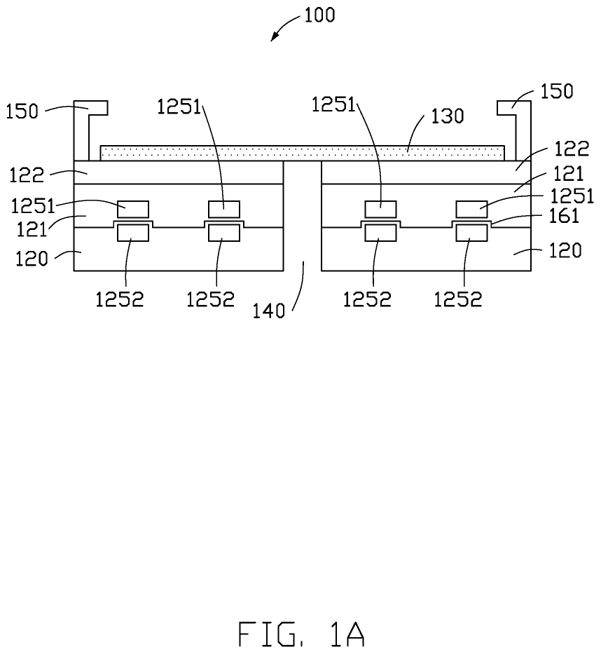

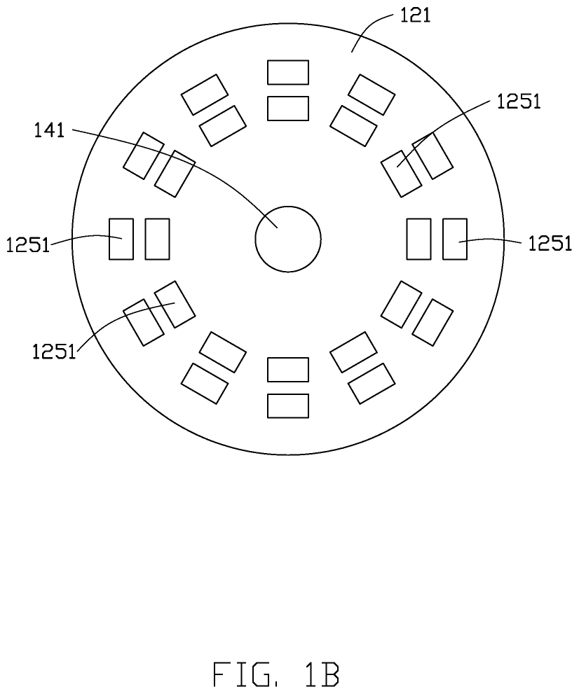

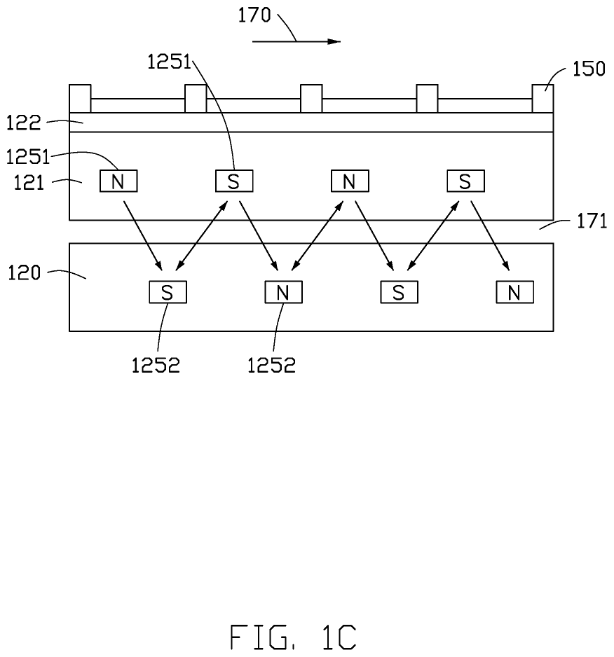

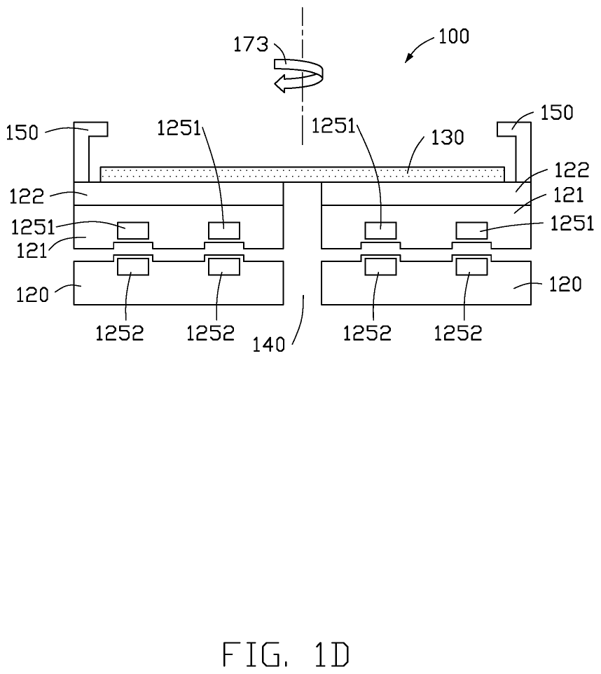

FIG. 1A illustrates a side cross-sectional view of a wafer spin-processing apparatus 100 in accordance with an implementation of the present disclosure. The wafer spin-processing apparatus 100 includes a base member 120, a rotatable member 121 disposed over the base member 120, and a wafer guide 122 disposed over the rotatable member 121 for holding a wafer 130. The base member 120 may be a stator or a lower chuck having a plurality of magnetic components 1252 such as electromagnets or coils. The rotatable member 121 may be a rotor or an upper chuck having a plurality of magnetic components 1251 such as superconducting magnets. The rotatable member 121 may be electromagnetically coupled to the base member 120. The wafer guide 122 may be affixed to the rotatable member 121. The wafer guide 122 may include a vacuum module (not shown) for retaining the wafer 130 over the rotatable member.

For example, a contact area 161 is formed between a top surface of the base member 120 and a bottom surface of the rotatable member 121. The base member 120 has protruded portions at the contact area 161. The magnetic components 1252 may be disposed near the protruded portions of the base member 120. The magnetic components 1251 of the rotatable member 121 are disposed in the positions corresponding to the magnetic components 1252 (e.g., recessed portions of the rotatable member 121). Preferably, the contact area 161 may be formed continuously.

In some implementations, the wafer spin-processing apparatus 100 includes a plurality of constraining guides 150 disposed at an edge of the wafer guide 122. The constraining guides 150 may prevent the wafer 130 from falling off during the spin process.

In some implementations, the wafer spin-processing apparatus 100 includes a passage 140 disposed along a vertical central axis thereof. From bottom to top, the passage 140 penetrates through the base member 120, the rotatable member 121, and the wafer guide 122.

FIG. 1B illustrates a top cross-sectional view of the rotatable member 121 of the wafer spin-processing apparatus 100. An opening 141 of the passage 140 is at the center of the rotatable member 121. Pairs of magnetic components 1251 are disposed so as to encircle the opening 141 (e.g., two parallelly arranged magnetic components 1251 are disposed side by side along the radial direction of the rotatable member 121). Preferably, the magnetic components 1252 of the base member 120 have similar configurations to the magnetic components 1251.

FIG. 1C illustrates a side view of the wafer spin-processing apparatus 100 in a levitating and rotating state. For the purpose of clarification, inner magnetic components (close to the opening 141 as shown in FIG. 1B) are not illustrated in FIG. 1C. The spin process may begin with activation of the magnetic levitation, in which the magnetic components 1252 of the base member 120 and the magnetic components 1251 of the rotatable member 121 repel each other. The base member 120 is stationary. The rotatable member 121 is levitated to form a gap 171 between the base member 120 and the rotatable member 121. Subsequent to the magnetic levitation, activation of magnetic rotation cause the rotatable member 121 to start spinning. An alternating current may be induced in the magnetic components 1252 to generate an alternating series of North and South magnetic poles for allowing the magnetic components 1251, 1252 to attract and repel each other. The magnetically driven rotation accelerates the rotatable member 121 in a tangential direction indicated by an arrow 170.

FIG. 1D illustrates a side cross-sectional view of the wafer spin-processing apparatus 100 in the levitating and rotating state. The rotatable member 121 spins counterclockwise as indicated by an arrow 173 using the mechanism elaborated above. The configuration of paired magnetic components, for example, aligned in radial directions, strengthens the magnetic force for levitation. The symmetry of such paired configuration increases the stability of the wafer spin-processing apparatus 100 during high speed spin process. In some implementations, the rotatable member 121 may spin clockwise.

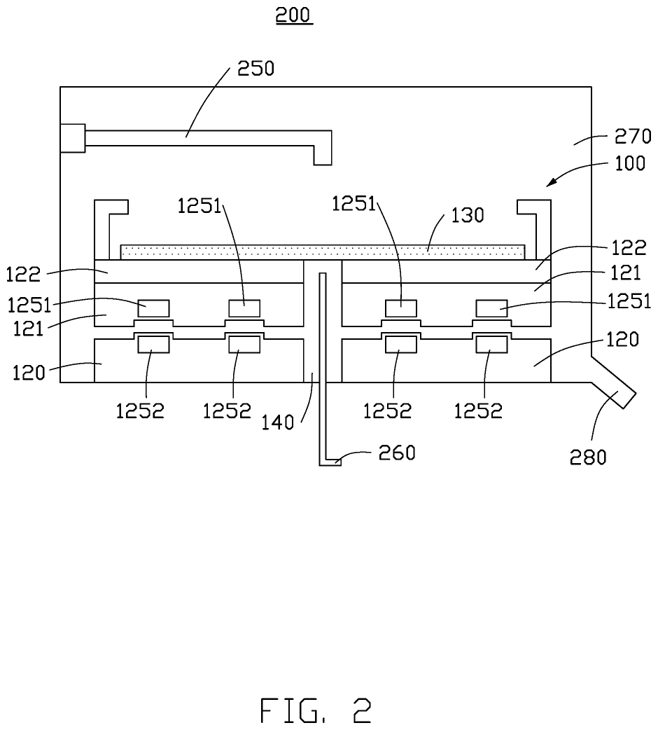

FIG. 2 illustrates a side cross-sectional view of a wafer spin-processing system 200 having the wafer spin-processing apparatus 100 in accordance with an implementation of the present disclosure. The wafer spin-processing system 200 includes a chamber 270, a first nozzle 250, a second nozzle 260, a drain 280, and the wafer spin-processing apparatus 100 disposed at the bottom of the chamber 270. The first nozzle 250 is configured to spray chemical liquid or gas on a front side of the wafer 130. The second nozzle 260 may be disposed in the passage 140 for spraying chemical liquid or gas on a back side of the wafer 130. The drain 280 may discharge waste chemical liquid or gas. In some implementations, the wafer guide 122 may include elevating pins (not shown) to lift the wafer 130 for generating space between the back side of the wafer 130 and the wafer guide 122 to allow the chemical liquid or gas to contact the back side of the wafer 130.

According to the exemplary implementations of the present disclosure, since the base member 120 of the wafer spin-processing apparatus 100 is stationary and connected to the bottom of the chamber 270 in a closed state, contamination of the wafer spin-processing apparatus 100 by condensed fumes generated during the spin process and the associated defects on the wafer are avoided.

The terminology used herein is for the purpose of describing particular implementations only and is not intended to be limiting of implementations of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to implementations of the present disclosure in the form disclosed. Many modifications and variations will be apparent to those of ordinary skill in the art without departing from the scope and spirit of implementations of the present disclosure. The implementation was chosen and described in order to best explain the principles of implementations of the present disclosure and the practical application, and to enable others of ordinary skill in the art to understand implementations of the present disclosure for various implementations with various modifications as are suited to the particular use contemplated.

Although specific implementations have been illustrated and described herein, those of ordinary skill in the art appreciate that any arrangement which is calculated to achieve the same purpose may be substituted for the specific implementations shown and that implementations of the present disclosure have other applications in other environments. This present disclosure is intended to cover any adaptations or variations of the present disclosure. The following claims are in no way intended to limit the scope of implementations of the present disclosure to the specific implementations described herein.

Various examples have been described. These and other examples are within the scope of the following claims.

What is claimed is:

1. An apparatus for performing a wafer spin process, the apparatus comprising:
a base member including a plurality of first magnetic components;
a rotatable member disposed over the base member and including a plurality of second magnetic components; and
a wafer guide disposed over the rotatable member for holding a wafer.

2. The apparatus of claim 1, wherein the rotatable member is electromagnetically coupled to the base member.

3. The apparatus of claim 1, wherein the rotatable member is magnetically levitated from the base member when the wafer spin process is performed.

4. The apparatus of claim 1, wherein the first magnetic components are electromagnets or coils.

5. The apparatus of claim 1, wherein the second magnetic components are superconducting magnets.

6. The apparatus of claim 1, further comprising a plurality of first pins at an edge of the wafer guide for confining the wafer.

7. The apparatus of claim 1, wherein the wafer guide includes a vacuum module for retaining the wafer over the rotatable member.

8. The apparatus of claim 1, wherein the wafer guide includes a plurality of second pins for lifting the wafer.

9. The apparatus of claim 1, further comprising a passage penetrating into the base member, the rotatable member, and the wafer guide.

10. The apparatus of claim 9, wherein the first magnetic components encircles the passage.

11. The apparatus of claim 9, wherein the second magnetic components encircles the passage.

12. A system for performing a wafer spin process, the system comprising:
a chamber; and
an apparatus disposed in the chamber, the apparatus comprising:
a base member comprising a plurality of first magnetic components;
a rotatable member disposed over the base member and comprising a plurality of second magnetic components; and
a wafer guide disposed over the rotatable member for holding a wafer.

13. The system of claim 12, further comprising a first nozzle for spraying liquid or gas on a front side of the wafer.

14. The system of claim 12, wherein the apparatus further comprises a passage penetrating the base member, the rotatable member, and the wafer guide.

15. The system of claim 14, further comprising a second nozzle disposed in the passage for spraying a liquid or a gas on a back side of the wafer.

16. The system of claim 12, wherein the chamber further comprises a drain to exhaust waste liquid or gas.

17. The system of claim 12, wherein the rotatable member is electromagnetically coupled to the base member.

18. The system of claim 12, wherein the first magnetic components comprise electromagnets or coils.

19. The system of claim 12, wherein the second magnetic components comprise superconducting magnets.

20. The system of claim 12, wherein the apparatus further comprises a plurality of first pins at an edge of the wafer guide for confining the wafer.
